(19) United States
(12) Patent Application Publication
(10) Pub. No.: US 2023/0377384 A1
(43) Pub. Date: Nov. 23, 2023

(54) SYSTEMS AND METHODS FOR DETERMINING VEHICLE COMPONENT HEALTH STATUS

(71) Applicant: Verizon Patent and Licensing Inc., Basking Ridge, NJ (US)

(72) Inventor: Jeyanth Paul JOHN BRITTO, Alpharetta, GA (US)

(73) Assignee: Verizon Patent and Licensing Inc., Basking Ridge, NJ (US)

(21) Appl. No.: 17/663,894

(22) Filed: May 18, 2022

(51) Int. Cl. G07C 5/08; G07C 5/00; G01R 31/3835; G01L 13/00

(52) U.S. Cl. CPC G07C 5/0808; G07C 5/008; G01R 31/3835; G01L 13/00

(57) ABSTRACT

In some implementations, a device may receive, from one or more vehicle telematics devices, vehicle data indicating information relating to one or more vehicle components of a vehicle. The device may determine a geographical region, of a plurality of geographical regions, associated with the vehicle. The plurality of geographical regions may be formed from a plurality of geographical areas having similarities in one or more environmental factors. The device may compare the vehicle data with one or more vehicle component health profiles corresponding to the vehicle component(s). The vehicle component health profile(s) may be based at least in part on the geographical region associated with the vehicle. The vehicle component health profile(s) may indicate failure thresholds for the vehicle component(s). The device may determine a health status of the vehicle component(s) based on comparing the vehicle data with the vehicle component health profile(s).

### BACKGROUND

Vehicle telematics devices can be used to gather information about a vehicle and/or a driver of the vehicle. In general, vehicle telematics devices can access various data relating to the operation of the vehicle by interfacing with a vehicle communication interface of the vehicle (e.g., via a controller area network (CAN), an on-board diagnostics (OBD) port, and/or another information system within the vehicle). Vehicle telematics devices can also provide dedicated sensors or measurement devices adapted to gather additional data about the vehicle and/or driver that may not otherwise be determined directly from the vehicle. Vehicle telematics devices can also send, receive, and/or store the data via a wired and/or wireless communication interface with a smart phone, a computer, a cellular network, and/or the like.

### BRIEF DESCRIPTION OF THE DRAWINGS

FIGS. 1A-1F are diagrams of an example associated with determining vehicle component health status.

FIG. 2 is a diagram of an example environment in which systems and/or methods described herein may be implemented.

FIG. 3 is a diagram of example components of one or more devices of FIG. 2.

FIG. 4 is a diagram of example components of one or more devices of FIG. 2.

FIG. 5 is a flowchart of an example process relating to determining vehicle component health status.

### DETAILED DESCRIPTION OF EXAMPLE EMBODIMENTS

The following detailed description of example implementations refers to the accompanying drawings. The same reference numbers in different drawings may identify the same or similar elements.

Timely vehicle maintenance is an important aspect of owning and operating a vehicle. Proper performance of a vehicle relies on the ability of different vehicle components to perform different functions of the vehicle. Many of the components of a vehicle are wear items that need to be serviced or replaced after a particular amount of use or at certain intervals, typically tracked in terms of distance driven and/or expiration of a time period. Some of the more common wear items of a vehicle may include, for example, tires, batteries, brake pads, filters, brake rotors, wheel bearings, emission components, shock absorbers, and the like. Other common vehicle components that are regularly serviced may also include fluids, such as engine oil, transmission oil, coolant, brake fluid, and the like.

As such wear items deteriorate, various functions of the vehicle can suffer in terms of safety, performance, efficiency, and/or fuel economy. For instance, worn tires may provide less traction and reduce the ability to effectively stop or steer the vehicle, especially on wet or snowy road surfaces. Operating a vehicle with worn components may further adversely affect or accelerate the wear of other vehicle components that are otherwise in optimal condition. For instance, driving on worn tires for prolonged periods of time may accelerate the wear of wheel bearings, suspension components, transmission components, and/or other vehicle components. Prolonged use of worn brake pads may accelerate the wear of brake rotors, brake calipers, brake lines, and/or other related components. Furthermore, prolonged use of older batteries may accelerate the wear of alternators and/or other electrical components.

While timely maintenance helps to keep the vehicle operating at optimal levels, it is often difficult to identify the appropriate time to service a particular vehicle component. General service intervals for some vehicle components may exist, but tend to be broadly defined and do not take into account factors specific to the vehicle and/or driver, such as driving behavior, driving location, local climate, and/or another factor that can significantly affect the actual wear of the particular vehicle component. For instance, a particular tire that is installed on a heavy vehicle that is driven by an aggressive driver on unpaved roads in warmer climates may have a significantly shorter life than when installed on a light vehicle, that is driven by a slow driver on paved roads in cooler climates. With such variance, following general service intervals may result in untimely vehicle service.

In some cases, a driver of a vehicle may independently monitor the actual wear of the vehicle components between service intervals, and determine firsthand when service is needed. However, assessing the condition of a vehicle component is not always straightforward. The driver may need to research (e.g., query Internet resources via a computer or a mobile device) to understand when a vehicle component needs to be replaced, to select which replacement vehicle component fits the vehicle and the desired vehicle use, and/or to identify local service centers that are capable of replacing the particular vehicle component. The driver may also consult with a representative of a service center. However, the service center representative may also need to refer to internal resources (e.g., data stored on a network workstation and/or server) to determine the correct replacement component and verify fitment for the particular vehicle. Such research can be time-consuming and use computational and/or network resources (e.g., processing resources, memory resources, power resources, communication resources, and/or the like).

Some implementations described herein enable a system to monitor the health of one or more vehicle components of a vehicle and determine the health status of the vehicle component(s) based on vehicle data received from the vehicle (e.g., from vehicle telematic devices) and compare the received vehicle data to vehicle component health profiles corresponding to the particular vehicle component(s). The health profiles may be based on geographical regions, which may be formed from geographical areas having similarities in one or more environmental factors (e.g., temperature and/or precipitation). Accordingly, based on a geographic location of the vehicle (e.g., as indicated by the vehicle data), the system may determine the geographical region in which the vehicle is located, and compare the vehicle data with the health profile corresponding to the geographical region associated with the vehicle.

In this way, the health monitoring system is able to provide a more accurate health status of various vehicle components and, therefore, better predictions about a vehicle (e.g., when failure of a particular vehicle component is going to occur) without the drawbacks discussed above. By maintaining the vehicle components in optimal condition, the driver is able to keep the vehicle operating safely, efficiently, and with better fuel economy. Furthermore, by using the health monitoring system, drivers and/or service centers are able to conserve computational and network resources (e.g., processing resources, memory resources, power resources, communication resources, and/or the like).

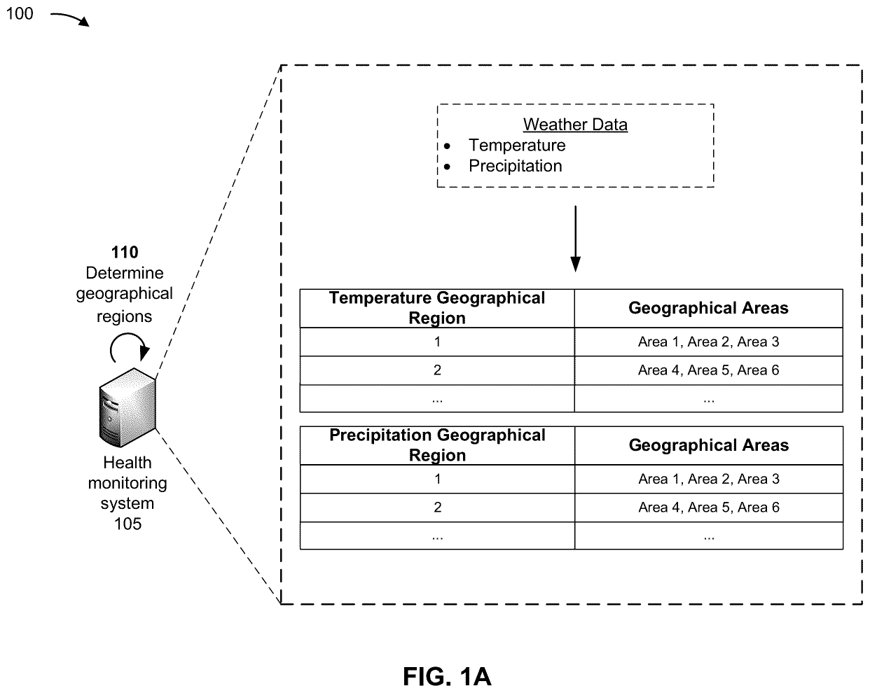

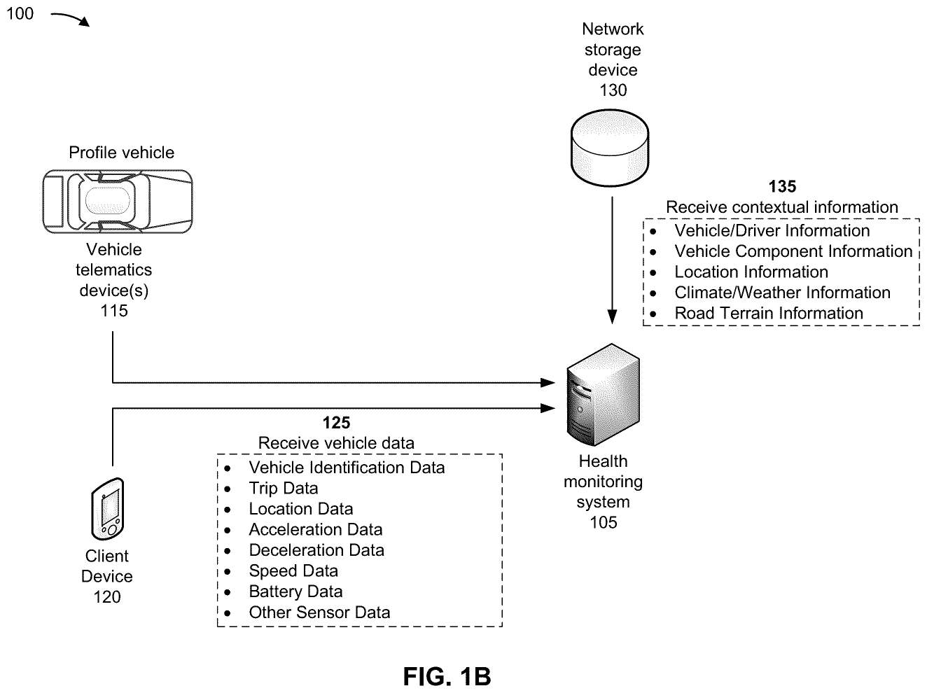

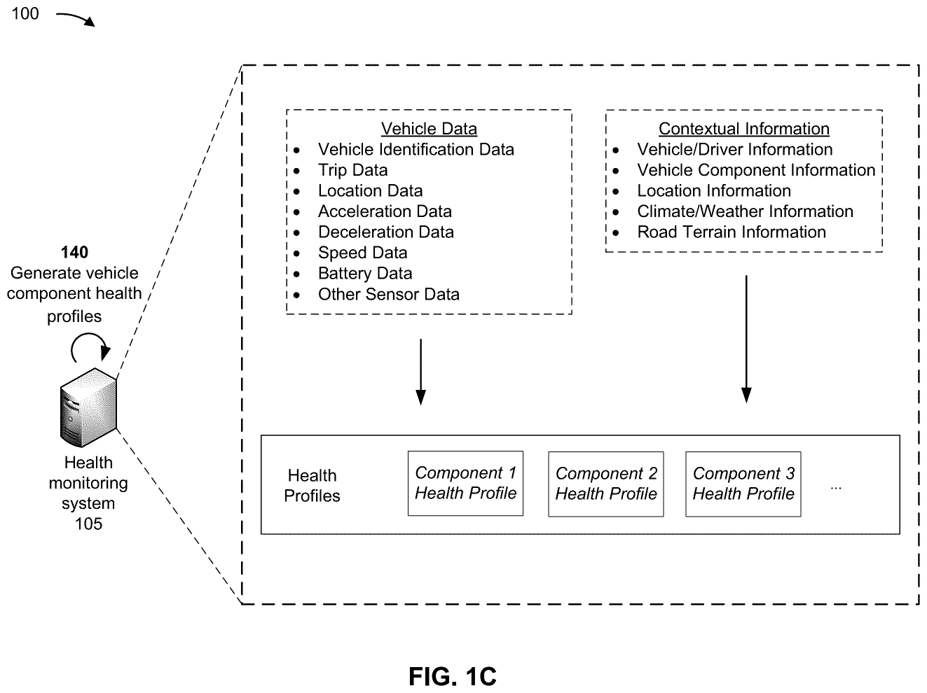

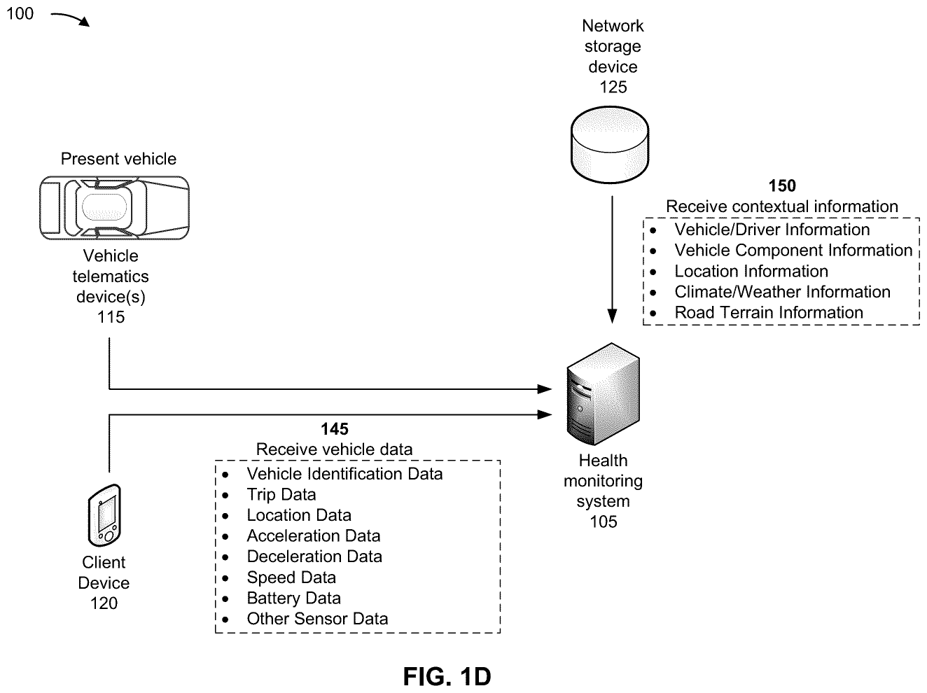

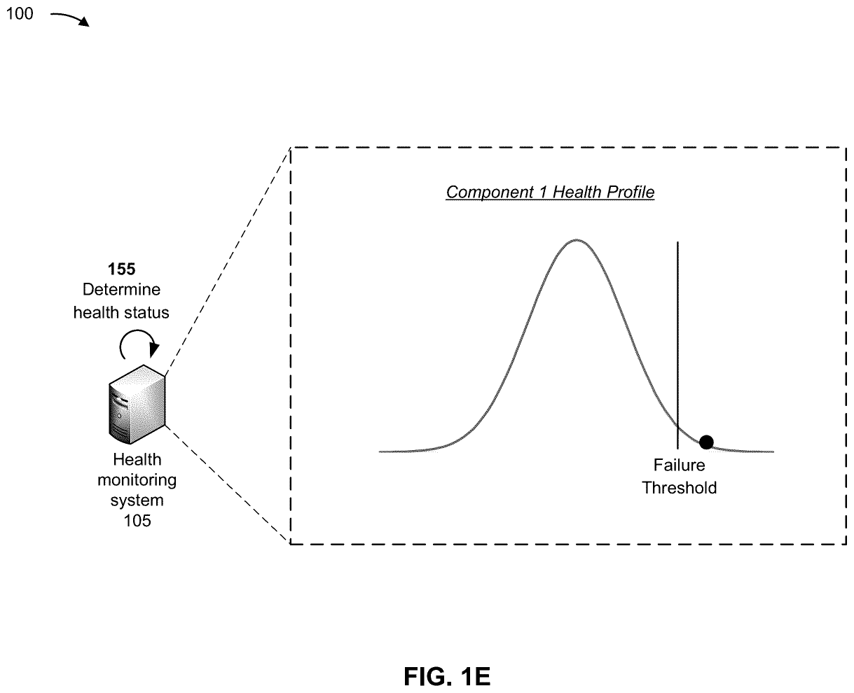

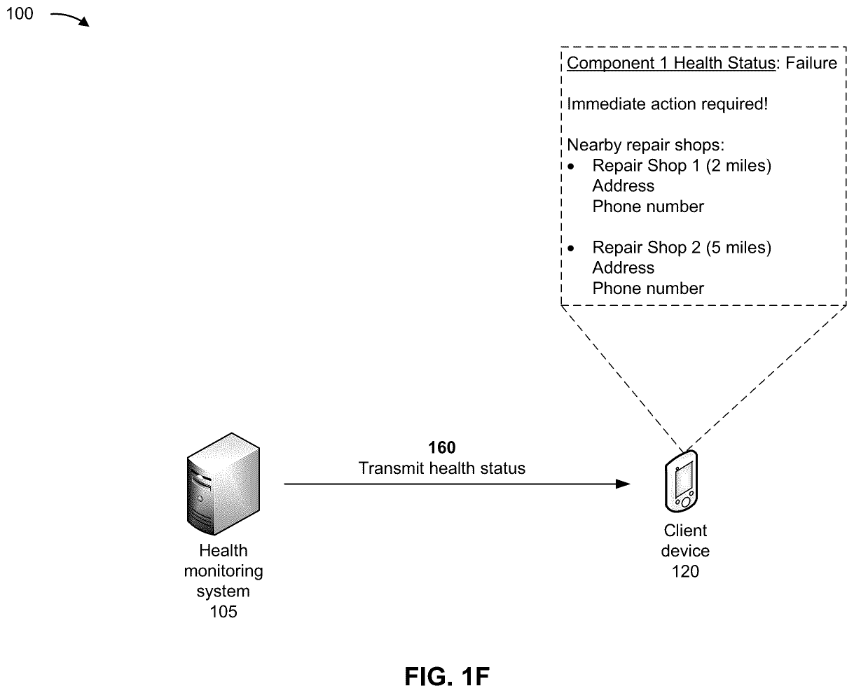

FIGS. 1A-1F are diagrams of an example 100 associated with determining vehicle component health status of one or more vehicle components of a vehicle. As shown in FIGS. 1A-1F, example 100 includes a health monitoring system 105, one or more vehicle telematics devices 115, a client device 120, and a network storage device 130. The health monitoring system 105 may provide a vehicle component health tracking service that tracks a health status of a vehicle component. FIGS. 1A-1F present one or more functions that may be performed by the health monitoring system 105 to provide the vehicle component health tracking service. For example, the health monitoring system may receive vehicle data, estimate a wear rate based on the vehicle data, and determine the health status for the vehicle component based on the vehicle data. In some implementations, one or more of the functions, described as being performed by the health monitoring system 105, may be performed by another device, such as the client device 120.

In some implementations, the health monitoring system 105 may enable a driver (e.g., a vehicle owner) to register for the vehicle component health tracking service using the client device 120 (e.g., a smart phone, a mobile device, a computer, and/or the like). For example, the health monitoring system 105 may enable the driver to use the client device 120 to connect to the health monitoring system via a wired and/or a wireless connection, create a user account, and register for the vehicle component health tracking service. In some implementations, the health monitoring system 105 may enable the driver to submit via the client device 120, during and/or after the registration process, information regarding the driver, the vehicle, the vehicle component, and/or the condition of the vehicle component. In some implementations, the health monitoring system 105 may enable the driver to register the vehicle telematics device(s) 115 and/or the client device 120 to be associated with the user account, the driver, and/or the vehicle.

In some implementations, the vehicle component health tracking service may be provided to the client device 120 via a client application that is installed on the client device 120. In some implementations, the vehicle component health tracking service may be provided to the client device 120 via a web-based application that is hosted by the health monitoring system 105. Using the vehicle component health tracking service, the driver may be able to specify when the health monitoring system 105 should receive the vehicle data and/or how much of the vehicle data the health monitoring system 105 should receive. For example, the driver may manually instruct the health monitoring system 105 to start and/or stop receiving vehicle data from the vehicle telematics device(s) 115 and/or the client device 120 at a desired interval. Additionally, or alternatively, the driver may specify a condition under which the health monitoring system 105 is to automatically start and/or stop receiving vehicle data (e.g., at a particular time, on a particular day, and/or based on another trigger). In some implementations, the vehicle component health tracking service may configure the vehicle telematics device(s) 115 and/or the client device 120 to automatically store the vehicle data in a local memory, and enable the driver to manually select when the health monitoring system 105 should receive the vehicle data and/or how much of the vehicle data to transmit to the health monitoring system 105.

As described in more detail hereinafter, to provide the vehicle component health tracking service for a particular vehicle associated with the user account (referred to as the account vehicle), the health monitoring system 105 may compare the vehicle data received from the vehicle telematics device(s) 115 and/or the client device 120 with health profiles corresponding to different vehicle components. The health profiles may be based, at least in part, on vehicle data accumulated from other vehicles (referred to as profile vehicles) and on geographical regions in which the profile vehicles are located when the vehicle data is accumulated.

As shown in FIG. 1A, and by reference number 110, the health monitoring system 105 may determine the geographical regions based, at least in part, on similarities in one or more environmental factors. For example, the geographical regions each may be formed from a group of geographical areas (e.g., cities, counties, states, or countries) that have similarities in one or more environmental factors (e.g., temperature, precipitation, and/or humidity). As an example, one environmental factor may include temperatures associated with the group of geographical areas. The geographical areas may have similarities if the respective temperatures are within a temperature threshold (e.g., 5 degrees Fahrenheit (F) or 10 degrees F.) from a set temperature value (e.g., an average temperature of the temperatures corresponding to the geographical areas). The temperatures associated with the geographical areas may be averages for the geographical areas across a certain timeframe (e.g., a month, 6 months, a year, or a particular season). For example, the geographical areas may each have an average temperature in the fall season within 5 degrees of 75 degrees F.

As another example, another environmental factor may include precipitation (e.g., rainfall and/or snowfall) associated with the group of geographical areas. The geographical areas may have similarities if the respective precipitation amount is within an amount threshold (e.g., 0.1 inches, 0.2 inches, or 0.5 inches) of a set value (e.g., an average precipitation accumulation of the precipitation amounts corresponding to the geographical areas). The precipitation amounts associated with the geographical areas may be total accumulation for the geographical areas across a certain timeframe (e.g., a month, 6 months, a year, or a particular season). For example, the geographical areas may each have a total accumulation for a calendar year within 0.2 inches of a total accumulation value of 2 inches.

The health monitoring system 105 may obtain data associated with the one or more environmental factors from a third-party source and/or database (e.g., a weather tracking service). The data may be obtained for a set timeframe (e.g., a previous calendar year). The health monitoring system 105 may apply one or more comparison measures (e.g., a cosine similarity measure) to determine the similarities in the environmental facts, and therefore, to determine the geographical regions.

As shown in FIG. 1B, and by reference number 125, the health monitoring system 105 may receive the vehicle data from the vehicle telematics device(s) 115 and/or the client device 120 associated with the profile vehicles. The vehicle data may include information that is supported by the vehicle telematics device(s) 115 and/or the client device 120 and relates to the driver, the vehicle, the vehicle component, and/or the condition of the vehicle component. For example, the health monitoring system 105 may receive vehicle data including vehicle identification data, trip data, location data, acceleration data (e.g., longitudinal acceleration and/or lateral acceleration), deceleration data, speed data, battery data (e.g., battery voltage), air filter pressure data (e.g., pressure differential), and/or other supported sensor data. Additionally, or alternatively, the health monitoring system 105 may receive user-supplied vehicle and/or vehicle component information in the form of textual data. In some implementations, the health monitoring system 105 may receive user-supplied information in the form of image data, audio data, video data, and/or another format of data.

In some implementations, the vehicle telematics device(s) 115 may be in communication with the vehicle (e.g., coupled to a communication interface of the vehicle via an On-Board Diagnostics (OBD) port, and/or the like), and configured to read sensor information relating to an electrical system, a mechanical system, an emission system, and/or another system of the vehicle. Additionally, or alternatively, the vehicle telematics device(s) 115 may include one or more sensors (e.g., an accelerometer, a gyroscope, a global positioning system (GPS) sensor, a magnetometer, a proximity sensor, a barometer, a camera, an audio sensor, a temperature sensor, and/or the like) that are separate from the vehicle, but configured to monitor usage of the vehicle. In some implementations, the vehicle telematics device(s) 115 may be integrated within the vehicle (e.g., via an infotainment system, a navigation system, and/or the like).

In some implementations, the client device 120 may be associated with the driver of the vehicle and provide a user interface configured to receive user-supplied information. For example, the client device 120 may receive information regarding the vehicle (e.g., a vehicle identification number (VIN), a make, a model, a model year, a trim, a classification, a drive type, and/or another attribute of the vehicle). In some implementations, the client device 120 may receive information regarding the vehicle component (e.g., a part brand, a part model, a part number, a dimension, a performance rating, and/or another attribute of the vehicle component). In some implementations, the client device 120 may include one or more sensors (e.g., an accelerometer, a gyroscope, a GPS sensor, a magnetometer, a proximity sensor, a barometer, a camera, an audio sensor, a temperature sensor, and/or the like) that are configured to monitor usage of the vehicle.

In some implementations, the client device 120 may be configured to receive information regarding the vehicle, the vehicle component, and/or the condition of the vehicle component from the driver. For example, the client device 120 may enable the driver to enter information regarding the vehicle (e.g., a VIN, a make, a model, a model year, a trim, a classification, a drive type, and/or the like). Additionally, or alternatively, the client device 120 may enable the driver to enter information regarding the vehicle component (e.g., a part brand, a part model, a part number, a dimension, a performance rating, and/or another attribute of the vehicle component). Additionally, or alternatively, the client device 120 may enable the driver to enter information regarding the condition of the vehicle component (e.g., a physical dimension, a physical appearance, an electrical property, and/or another property indicative of the condition of the vehicle component).

The health monitoring system 105 may store the vehicle data obtained from the vehicle telematics device(s) 115 and/or the client device 120 (e.g., in a memory of the health monitoring system 105 and/or in the network storage device 130). The vehicle data may be grouped based on the geographical regions associated with the profile vehicles when the vehicle data was obtained. Additionally, or alternatively, the vehicle data may be grouped based on the information regarding the profile vehicles (e.g., the makes, models, model years, and/or trims) and/or the information regarding the vehicle components (e.g., part brand, part model, and/or part number).

As further shown in FIG. 1B, and by reference number 135, the health monitoring system 105 may optionally or additionally receive contextual information regarding the profile vehicle, the driver of the profile vehicle, and/or the geographical region in which the profile vehicle is located (e.g., vehicle and/or driver information, vehicle component information, location information, climate/weather information, and/or road terrain information) from a network storage device 130. In some implementations, the network storage device 130 may store reference data (e.g., a vehicle record, a service record, a maintenance record, a vehicle catalogue, a part diagram, a driving record, map data, traffic data, weather data, and/or road terrain data). In some implementations, the network storage device may be managed by the health monitoring system 105. In some implementations, the network storage device 130 may be accessible to the health monitoring system 105, but separately managed by a third-party associated with a service for maintaining the reference data.

As shown in FIG. 1C, and by reference number 140, the health monitoring system 105 may generate health profiles associated with the different vehicle components based at least in part on the vehicle data (also referred to as the collected vehicle data) received from the vehicle telematics device(s) 115 and/or the client device 120 associated with the profile vehicles.

In some implementations, the health profiles for each vehicle component may be associated with a particular geographical region (e.g., a particular vehicle component may have multiple health profiles for different geographical regions). In some implementations, the health profile for each vehicle component may be associated with a particular environmental factor and the corresponding geographical region. For example, for a vehicle component of a battery, the environmental factor on which a battery health profile is based may be temperature associated with the geographical areas forming the geographical regions, and therefore the battery health profile may be associated with temperature geographical regions. As another example, for a vehicle component of an air filter, the environmental factor on which an air filter health profile is based may be precipitation associated with the geographical areas forming the geographical regions, and therefore the air filter health profile may be associated with precipitation geographical regions. As another example, for a vehicle component of a brake pad, the environmental factor on which a brake pad health profile is based may be precipitation associated with the geographical areas forming the geographical regions, and therefore the brake pad health profile may be associated with precipitation geographical regions. As another example, for a vehicle component of a tire, the environmental factor on which a tire health profile is based may be temperature associated with the geographical areas forming the geographical regions, and therefore the tire health profile may be associated with temperature geographical regions.

Additionally, or alternatively, the health profiles for each vehicle component may be associated with a particular vehicle make, model, model year, and/or trim. Additionally, or alternatively, the health profiles for each vehicle component may be associated with a particular part brand, part model, and/or part number.

To generate the health profile for a particular vehicle component, the health monitoring system 105 may determine a relationship between measurements, as indicated by the vehicle data, associated with the particular vehicle component and time until failure of the particular vehicle component occurs. For example, the relationship may follow a bell curve with a corresponding mean. In some implementations, failure of the particular vehicle component may occur when the measurement meets a failure threshold (e.g., is above the failure threshold or below the failure threshold, depending on the particular vehicle component and associated measurement). Additionally, or alternatively, failure of the particular vehicle component may be determined if a user of a particular profile vehicle provides update information to the health monitoring system 105 (e.g., to a user account associated with the particular user) that the particular vehicle component has been replaced.

In some implementations, the health profiles for each vehicle component may be further based on a driver profile (e.g., cautious or aggressive) of the driver. The driver profile may be based on the driver's history and may be associated with the driver's user profile. The driver profile may be determined based at least in part on a number of times in the driver's history that one or more conditions have been satisfied. For example, a condition may include a measurement, which corresponds to at least one driving factor (acceleration, braking, and/or cornering) exceeding a threshold or minimum duration. The health profile, including the failure threshold, for a particular vehicle component may vary depending on the driver profile (e.g., whether the driver is cautious or aggressive). For example, the failure threshold may be less for an aggressive driver profile than for a cautious driver profile.

Additionally, or alternatively, the health profiles may be based on road terrain. For example, different roads may be classified as a particular road terrain (e.g., a highway terrain, a local terrain, or a rural terrain). The roads may be pre-classified and stored in a database accessible by the health monitoring system 105 (e.g., the network storage device 130). Additionally, or alternatively, the health monitoring system 105 may classify the particular road on which the profile vehicles are driving when receiving the vehicle data based on the vehicle data (e.g., shock displacement or vehicle displacement). For example, the health monitoring system 105 may determine that the road is a highway if the shock displacement, as indicated by the vehicle data, is within a first range (e.g., less than 0.5 inches). The health monitoring system 105 may determine that the road is a local road if the shock displacement is within a second range (e.g., 0.5 inches to 1.5 inches). The health monitoring system 105 may determine that the road is a rural road if the shock displacement is within a third range (e.g., greater than 1.5 inches). The health profile, including the failure threshold, for a particular vehicle may vary depending upon the road terrain. For example, the failure threshold may be less for a rural road terrain than a highway road terrain or a local road terrain.

As shown in FIG. 1D, and by reference number 145, the health monitoring system 105 may receive vehicle data (also referred to as the account vehicle data) associated with the account vehicle (e.g., the vehicle associated with the user account and for which the vehicle health tracking service is tracking the health status of vehicle components). The health monitoring system 105 may receive the vehicle data (e.g., vehicle identification data, trip data, location data, acceleration data, deceleration data, speed data, battery data, air filter pressure data, and/or other supported sensor data) from the vehicle telematic device(s) 115 and/or the client device 120 associated with the account vehicle and/or the user account. Additionally, or alternatively, as shown by reference number 150, the health monitoring system 105 may receive contextual information (e.g., a vehicle record, a service record, a maintenance record, a vehicle catalogue, a part diagram, a driving record, map data, traffic data, weather data, and/or road terrain data) from the network storage device 130. The health monitoring system 105 may receive the vehicle data and/or the contextual information in a similar manner as with the profile vehicles explained above in connection with FIG. 1B.

As shown in FIG. 1E, and by reference number 155, the health monitoring system 105 may determine the health status of one or more vehicle components of the account vehicle based on the vehicle data and/or the contextual information regarding the account vehicle, the driver of the account vehicle, and/or the geographical region in which the account vehicle is located (e.g., vehicle and/or driver information, vehicle component information, location information, climate/weather information, and/or road terrain information) received from the vehicle telematic device(s) 115 and/or the client device 120 associated with the account vehicle. To determine the health status, the health monitoring system 105 may determine which geographical region is associated with the account vehicle. For example, the health monitoring system 105 may determine the geographical region based on location data (e.g., geographic coordinates) included in the vehicle data and/or contextual information. For each vehicle component, the health monitoring system 105 may obtain the corresponding health profile for the geographical region associated with the account vehicle. The health monitoring system 105 may then compare the vehicle data (e.g., measurements associated with the particular vehicle component) with the corresponding health profile.

The health monitoring system 105 may determine how many standard deviations away from the mean a measurement is. For example, if the measurement is within a healthy number of standard deviations away from the mean (e.g., within 1 standard deviation), then the health monitoring system may determine that the health status of the particular vehicle component is a healthy state. If the measurement is within a cautious number of standard deviations away from the mean (e.g., 2 or 3 standard deviations), then the health monitoring system may determine that the health status of the particular vehicle component is a cautious state (e.g., requiring attention soon). If the measurement is a failure number of standard deviations away from the mean, then the health monitoring system 105 may determine that the particular vehicle component is in a failure state (e.g., requiring immediate attention).

As an example in which one vehicle component includes a battery, a failure state of the battery occurs when a voltage measurement is at least a failure number of standard deviations below the mean of the battery health profile. As another example in which one vehicle component includes an air filter, a failure state of the air filter occurs when a pressure differential measurement is at least a failure number of standard deviations above the mean of the air filter health profile. As another example in which one vehicle component includes one or more brake pads, a failure state of the one or more brake pads occurs when a number of harsh braking events is at least a number of standard deviations above the mean of the brake pad health profile. A harsh braking event may occur when the deceleration, as indicated by the account vehicle data, exceeds a braking threshold (e.g., 0.6 Gs). As another example in which one vehicle component includes one or more tires, a failure state of the one or more tires occurs when a cumulative number of harsh braking events, harsh acceleration events, and harsh cornering events is at least a number of standard deviations above the mean of the tire health profile. A harsh acceleration event may occur when the longitudinal acceleration exceeds an acceleration threshold (e.g., 0.4 Gs). In some implementations, a harsh cornering event occurs when the lateral acceleration exceeds a cornering threshold (e.g., 0.3 Gs).

As shown in FIG. 1F, and by reference number 160, the health monitoring system 105 may transmit, to a client device (e.g., a device associated with the user/driver) vehicle component health data indicating the health status of a particular vehicle component. The health status may be provided in the form of a message or an alert on the client device 120 (e.g., in an application installed on the client device 120 or a short message service (SMS) message).

In some implementations, if the health status for a particular vehicle component is a failure state, then the health monitoring system 105 may identify (e.g., from a third-party database) one or more repair shops capable of addressing the failed vehicle component and that may be within a distance threshold from the account vehicle (e.g., 5 miles, 10 miles, or 15 miles). The health monitoring system 105 may transmit, to the client device 120, repair shop data indicating one or more repair shops and the associated information (e.g., address and/or phone number).

As described above, the health monitoring system is able to provide more accurate determinations of the health status of various vehicle components of a vehicle by considering the geographic location of the vehicle, as certain environmental factors (e.g., temperature and/or precipitation) may have a greater effect on the health of particular vehicle components. Accordingly, the vehicle components may be maintained in optimal condition, and the driver is able to keep the vehicle operating safely, efficiently, and with better fuel economy. Furthermore, by using the health monitoring system, drivers and/or service centers are able to conserve computational and network resources (e.g., processing resources, memory resources, power resources, communication resources, and/or the like).

As indicated above, FIGS. 1A-1F are provided as an example. Other examples may differ from what is described with regard to FIGS. 1A-1F. The number and arrangement of devices shown in FIGS. 1A-1F are provided as an example. In practice, there may be additional devices, fewer devices, different devices, or differently arranged devices than those shown in FIGS. 1A-1F. Furthermore, two or more devices shown in FIGS. 1A-1F may be implemented within a single device, or a single device shown in FIGS. 1A-1F may be implemented as multiple, distributed devices. Additionally, or alternatively, a set of devices (e.g., one or more devices) shown in FIGS. 1A-1F may perform one or more functions described as being performed by another set of devices shown in FIGS. 1A-1F.

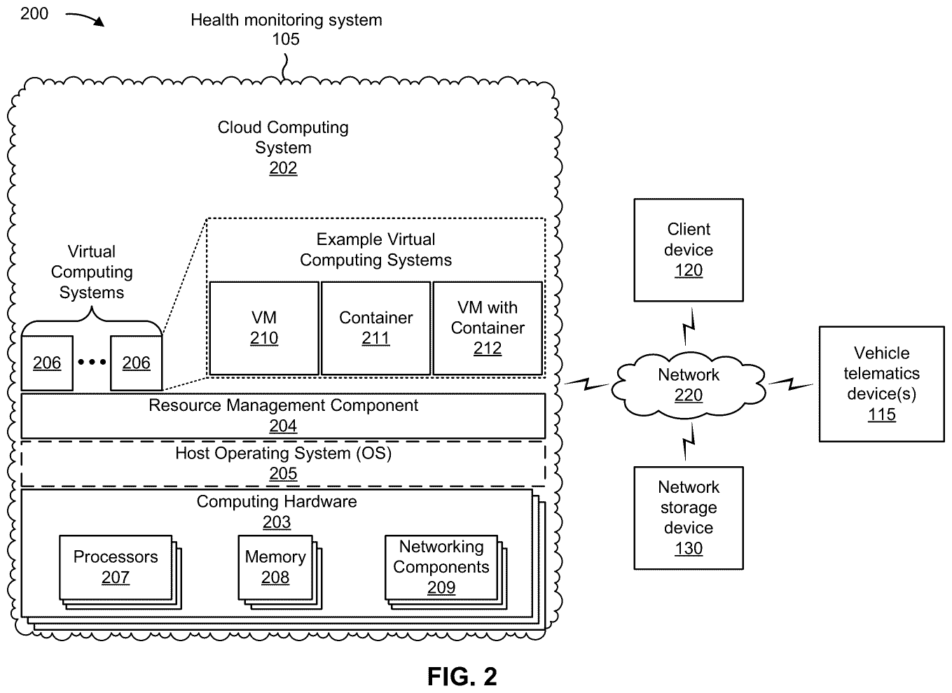

FIG. 2 is a diagram of an example environment 200 in which systems and/or methods described herein may be implemented. As shown in FIG. 2, environment 200 may include a health monitoring system 105, which may include one or more elements of and/or may execute within a cloud computing system 202. The cloud computing system 202 may include one or more elements 203-212, as described in more detail below. As further shown in FIG. 2, environment 200 may include the vehicle telematics device(s) 115, the client device 120, the network storage device 130, and/or a network 220. Devices and/or elements of environment 200 may interconnect via wired connections and/or wireless connections.

The vehicle telematics device(s) 115 include one or more devices capable of receiving, generating, storing, processing, and/or providing vehicle data. For example, the vehicle telematics device(s) 115 may include a group of sensors associated with determining driving information, such as an accelerometer, a gyroscope, a GPS sensor, a magnetometer, a proximity sensor, a barometer, a camera, an audio sensor, a temperature sensor, and/or the like. In some implementations, the vehicle telematics device(s) 115 may be installed during manufacture of the vehicle. Alternatively, the vehicle telematics device(s) 115 may be installed post-manufacture as an aftermarket device. In some implementations, the vehicle telematics device(s) 115 may be coupled to and/or communicate with a communication interface of the vehicle (e.g., via an OBD port, and/or the like). In some implementations, the vehicle telematics device(s) 115 may communicate over wireless and/or wired connections with the health monitoring system 105, the client device 120, the network storage device 130, and/or the like, via network 240.

The client device 120 includes one or more devices capable of receiving, generating, storing, processing, and/or providing information associated with determining vehicle component health status, as described elsewhere herein. The client device 120 may include a communication device and/or a computing device. For example, the client device 120 may include a wireless communication device, a mobile phone, a user equipment, a laptop computer, a tablet computer, a desktop computer, a wearable communication device (e.g., a smart wristwatch, a pair of smart eyeglasses, a head mounted display, or a virtual reality headset), or a similar type of device.

The network storage device 130 includes one or more devices capable of receiving, generating, storing, processing, and/or providing information associated with determining vehicle component health status, as described elsewhere herein. The network storage device 130 may include a communication device and/or a computing device. For example, the network storage device 130 may include a data structure, a database, a data source, a server, a database server, an application server, a client server, a web server, a host server, a proxy server, a virtual server (e.g., executing on computing hardware), a server in a cloud computing system, a device that includes computing hardware used in a cloud computing environment, or a similar type of device. As an example, the network storage device 130 may store vehicle data (e.g., vehicle identification data, trip data, location data, acceleration data, deceleration data, speed data, air filter pressure data, battery data, and/or other sensor data) and/or contextual information (e.g., vehicle and/or diver information, vehicle component information, location information, climate/weather information, and/or road terrain information), as described elsewhere herein.

The cloud computing system 202 includes computing hardware 203, a resource management component 204, a host operating system (OS) 205, and/or one or more virtual computing systems 206. The cloud computing system 202 may execute on, for example, an Amazon Web Services platform, a Microsoft Azure platform, or a Snowflake platform. The resource management component 204 may perform virtualization (e.g., abstraction) of computing hardware 203 to create the one or more virtual computing systems 206. Using virtualization, the resource management component 204 enables a single computing device (e.g., a computer or a server) to operate like multiple computing devices, such as by creating multiple isolated virtual computing systems 206 from computing hardware 203 of the single computing device. In this way, computing hardware 203 can operate more efficiently, with lower power consumption, higher reliability, higher availability, higher utilization, greater flexibility, and lower cost than using separate computing devices.

Computing hardware 203 includes hardware and corresponding resources from one or more computing devices. For example, computing hardware 203 may include hardware from a single computing device (e.g., a single server) or from multiple computing devices (e.g., multiple servers), such as multiple computing devices in one or more data centers. As shown, computing hardware 203 may include one or more processors 207, one or more memories 208, and/or one or more networking components 209. Examples of a processor, a memory, and a networking component (e.g., a communication component) are described elsewhere herein.

The resource management component 204 includes a virtualization application (e.g., executing on hardware, such as computing hardware 203) capable of virtualizing computing hardware 203 to start, stop, and/or manage one or more virtual computing systems 206. For example, the resource management component 204 may include a hypervisor (e.g., a bare-metal or Type 1 hypervisor, a hosted or Type 2 hypervisor, or another type of hypervisor) or a virtual machine monitor, such as when the virtual computing systems 206 are virtual machines 210. Additionally, or alternatively, the resource management component 204 may include a container manager, such as when the virtual computing systems 206 are containers 211. In some implementations, the resource management component 204 executes within and/or in coordination with a host operating system 205.

A virtual computing system 206 includes a virtual environment that enables cloud-based execution of operations and/or processes described herein using computing hardware 203. As shown, a virtual computing system 206 may include a virtual machine 210, a container 211, or a hybrid environment 212 that includes a virtual machine and a container, among other examples. A virtual computing system 206 may execute one or more applications using a file system that includes binary files, software libraries, and/or other resources required to execute applications on a guest operating system (e.g., within the virtual computing system 206) or the host operating system 205.

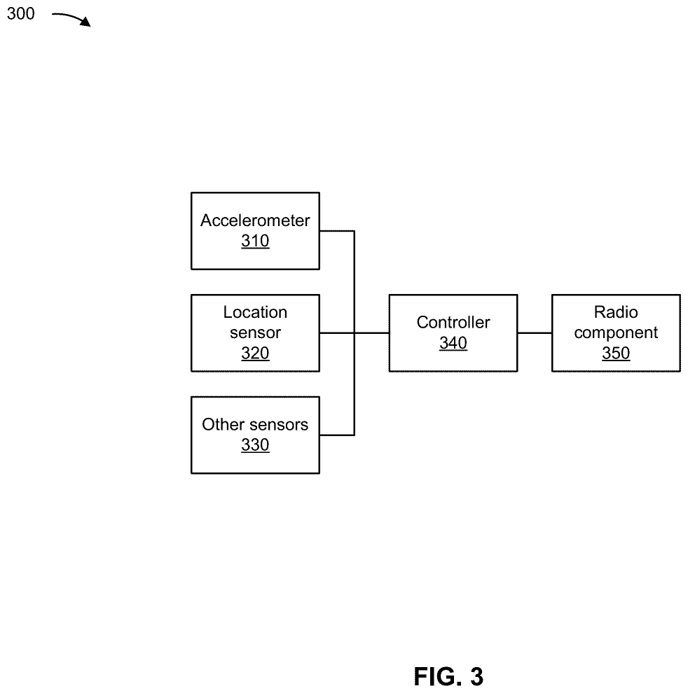

Although the health monitoring system 105 may include one or more elements 203-212 of the cloud computing system 202, may execute within the cloud computing system 202, and/or may be hosted within the cloud computing system 202, in some implementations, the health monitoring system 105 may not be cloud-based (e.g., may be implemented outside of a cloud computing system) or may be partially cloud-based. For example, the health monitoring system 105 may include one or more devices that are not part of the cloud computing system 202, such as device 300 of FIG. 3, which may include a standalone server or another type of computing device. The health monitoring system 105 may perform one or more operations and/or processes described in more detail elsewhere herein.

Network 220 includes one or more wired and/or wireless networks. For example, network 220 may include a cellular network, a public land mobile network (PLMN), a local area network (LAN), a wide area network (WAN), a private network, the Internet, and/or a combination of these or other types of networks. The network 220 enables communication among the devices of environment 200.

The number and arrangement of devices and networks shown in FIG. 2 are provided as an example. In practice, there may be additional devices and/or networks, fewer devices and/or networks, different devices and/or networks, or differently arranged devices and/or networks than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) of environment 200 may perform one or more functions described as being performed by another set of devices of environment 200.

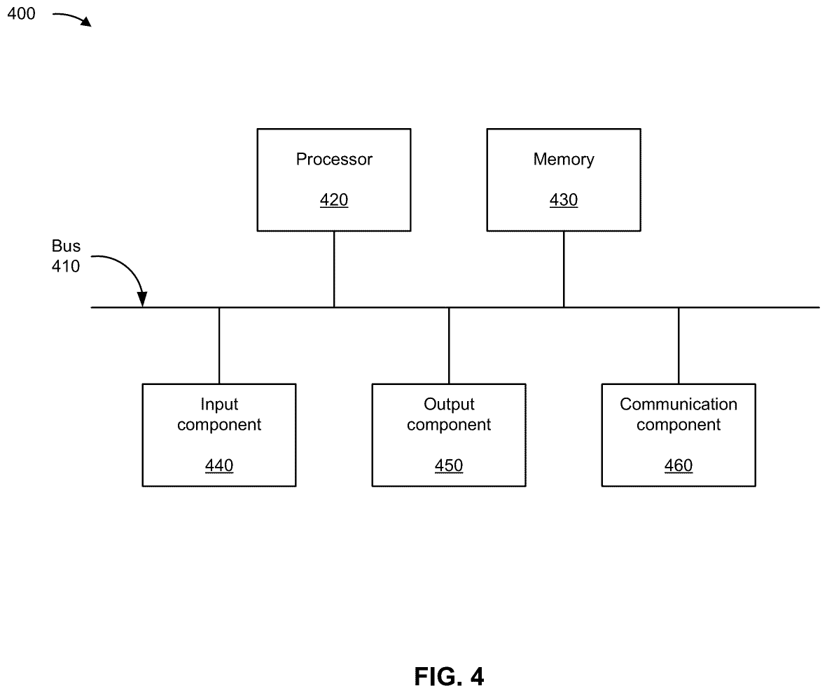

FIG. 3 is a diagram of example components of a device 300. Device 300 may correspond to the vehicle telematics device(s) 115 and/or the client device 120. Additionally, or alternatively, each of the vehicle telematics device(s) 115 and/or the client device 120 may include one or more devices 300 and/or one or more components of device 300. In some implementations, the vehicle telematics device(s) 115 and/or the client device 120 may include one or more other devices, such as a device shown in FIG. 4. As shown in FIG. 3, device 300 may include an accelerometer 310, a location sensor 320, other sensors 330, a controller 340, and/or a radio component 350.

Accelerometer 310 includes an accelerometer that is capable of measuring an acceleration, associated with a vehicle, and outputting information associated with the measured acceleration. For example, accelerometer 310 may measure the acceleration, and may output the acceleration as three acceleration values, each corresponding to an acceleration value associated with one of three orthogonal axes (e.g., an X-axis, a Y-axis, a Z-axis). In some implementations, the acceleration values, measured by accelerometer 310, may be provided to controller 340 for processing.

Location sensor 320 includes a sensor designed to determine a geographic location (e.g., a latitude, a longitude, and/or the like) of a device (e.g., the vehicle telematics device(s) 115 and/or the client device 120). For example, location sensor 320 may include a GPS sensor, a GLONASS-based sensor, or another type of sensor used to determine a location. In some implementations, the location data, determined by location sensor 320, may be provided to controller 340 for processing.

Other sensors 330 may include other environmental sensors capable of measuring information associated with determining driving information. For example, other sensors 330 may include a barometric pressure sensor, a gyroscope, a magnetometer, a proximity sensor, a temperature sensor, a light sensor (e.g., a photodiode sensor), an altimeter sensor, an infrared sensor, an audio sensor, or another type of sensor (e.g. a spectrometer, a humidity sensor, and/or the like). In some implementations, the sensor information, determined by other sensors 330, may be provided to controller 340 for processing.

Controller 340 includes a processor used to control the vehicle telematics device(s) 115 and/or the client device 120. In some implementations, controller 340 may include and/or be capable of communicating with a memory component that stores instructions for execution by controller 340. Additionally, or alternatively, controller 340 may determine, detect, store, and/or transmit driving information associated with a driver (e.g., based on sensor information received by controller 340).

Radio component 350 includes a component to manage a radio interface, such as a radio interface to wirelessly connect to network 220. For example, radio component 350 may provide an interface to a wireless cellular network (e.g., a ZigBee network, a Bluetooth network, a Wi-Fi network, and/or the like) associated with network 220. In some implementations, radio component 350 may include one or more antennae and corresponding transceiver circuitry.

The number and arrangement of components shown in FIG. 3 are provided as an example. In practice, device 300 may include additional components, fewer components, different components, or differently arranged components than those shown in FIG. 3. Additionally, or alternatively, a set of components (e.g., one or more components) of device 300 may perform one or more functions described as being performed by another set of components of device 300.

FIG. 4 is a diagram of example components of a device 400, which may correspond to the health monitoring system 105, the vehicle telematics device(s) 115, the client device 120, and/or the network storage device 130. In some implementations, the health monitoring system 105, the vehicle telematics device(s) 115, the client device 120, and/or the network storage device 130 include one or more devices 400 and/or one or more components of device 400. As shown in FIG. 4, device 400 may include a bus 410, a processor 420, a memory 430, an input component 440, an output component 450, and a communication component 460.

Bus 410 includes one or more components that enable wired and/or wireless communication among the components of device 400. Bus 410 may couple together two or more components of FIG. 4, such as via operative coupling, communicative coupling, electronic coupling, and/or electric coupling. Processor 420 includes a central processing unit, a graphics processing unit, a microprocessor, a controller, a microcontroller, a digital signal processor, a field-programmable gate array, an application-specific integrated circuit, and/or another type of processing component. Processor 420 is implemented in hardware, firmware, or a combination of hardware and software. In some implementations, processor 420 includes one or more processors capable of being programmed to perform one or more operations or processes described elsewhere herein.

Memory 430 includes volatile and/or nonvolatile memory. For example, memory 430 may include random access memory (RAM), read only memory (ROM), a hard disk drive, and/or another type of memory (e.g., a flash memory, a magnetic memory, and/or an optical memory). Memory 430 may include internal memory (e.g., RAM, ROM, or a hard disk drive) and/or removable memory (e.g., removable via a universal serial bus connection). Memory 430 may be a non-transitory computer-readable medium. Memory 430 stores information, instructions, and/or software (e.g., one or more software applications) related to the operation of device 400. In some implementations, memory 430 includes one or more memories that are coupled to one or more processors (e.g., processor 420), such as via bus 410.

Input component 440 enables device 400 to receive input, such as user input and/or sensed input. For example, input component 440 may include a touch screen, a keyboard, a keypad, a mouse, a button, a microphone, a switch, a sensor, a global positioning system sensor, an accelerometer, a gyroscope, and/or an actuator. Output component 450 enables device 400 to provide output, such as via a display, a speaker, and/or a light-emitting diode. Communication component 460 enables device 400 to communicate with other devices via a wired connection and/or a wireless connection. For example, communication component 460 may include a receiver, a transmitter, a transceiver, a modem, a network interface card, and/or an antenna.

Device 400 may perform one or more operations or processes described herein. For example, a non-transitory computer-readable medium (e.g., memory 430) may store a set of instructions (e.g., one or more instructions or code) for execution by processor 420. Processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry is used instead of or in combination with the instructions to perform one or more operations or processes described herein. Additionally, or alternatively, processor 420 may be configured to perform one or more operations or processes described herein. Thus, implementations described herein are not limited to any specific combination of hardware circuitry and software.

The number and arrangement of components shown in FIG. 4 are provided as an example. Device 400 may include additional components, fewer components, different components, or differently arranged components than those shown in FIG. 4. Additionally, or alternatively, a set of components (e.g., one or more components) of device 400 may perform one or more functions described as being performed by another set of components of device 400.

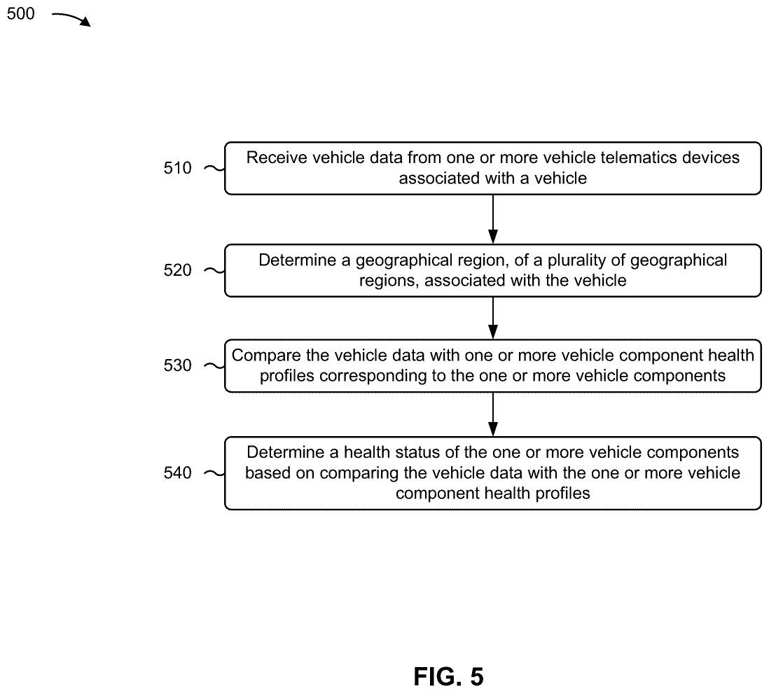

FIG. 5 is a flowchart of an example process 500 associated with determining vehicle component health status. In some implementations, one or more process blocks of FIG. 5 may be performed by a device (e.g., the health monitoring system 105). In some implementations, one or more process blocks of FIG. 5 may be performed by another device or a group of devices separate from or including the device, such as a client device (e.g., client device 120). Additionally, or alternatively, one or more process blocks of FIG. 5 may be performed by one or more components of device 400, such as processor 420, memory 430, input component 440, output component 450, and/or communication interface 460.

As shown in FIG. 5, process 500 may include receiving vehicle data from one or more vehicle telematics devices (block 510). For example, the device may receive vehicle data from one or more vehicle telematics devices, as described above. In some implementations, the vehicle data indicates information relating to one or more vehicle components of a vehicle.

In some implementations, one vehicle component, of the one or more vehicle components, includes a battery, wherein the information indicated by the vehicle data includes a plurality of voltage measurements of the battery. In some implementations, one vehicle component, of the one or more vehicle components, includes an air filter, wherein the information indicated by the vehicle data includes a plurality of pressure differential measurements across the air filter. In some implementations, one vehicle component, of the one or more vehicle components, includes one or more brake pads, wherein the information indicated by the vehicle data includes deceleration. In some implementations, one vehicle component, of the one or more vehicle components, includes one or more tires, wherein the information indicated by the vehicle data includes lateral acceleration, longitudinal acceleration, and deceleration.

As further shown in FIG. 5, process 500 may include determining a geographical region, of a plurality of geographical regions, associated with the vehicle (block 520). For example, the device may determine a geographical region, of a plurality of geographical regions, associated with the vehicle, as described above. In some implementations, the plurality of geographical regions are formed from a plurality of geographical areas that have similarities in one or more environmental factors associated with the plurality of geographical areas. In some implementations, the one or more environmental factors includes one or more of temperature, precipitation, or humidity associated with the plurality of geographical areas.

As further shown in FIG. 5, process 500 may include comparing the vehicle data with one or more vehicle component health profiles corresponding to the one or more vehicle components (block 530). For example, the device may compare the vehicle data with one or more vehicle component health profiles corresponding to the one or more vehicle components, as described above. In some implementations, the one or more vehicle component health profiles are based at least in part on the geographical region associated with the vehicle. In some implementations, the one or more vehicle component health profiles indicate failure thresholds for the one or more vehicle components. In some implementations, the failure thresholds are based on corresponding numbers of standard deviations from corresponding means of the one or more vehicle component health profiles.

In some implementations, the one or more vehicle component health profiles are further based on road terrain, and the road terrain is classified in one of a plurality of categories including a highway terrain, a local terrain, and a rural terrain. In some implementations, the one or more vehicle component health profiles are further based on a driver profile, and the driver profile is determined based at least in part on one or more conditions. In some implementations, the one or more conditions include a measurement, which corresponds to at least one driving factor, exceeding a threshold or a minimum duration, and the at least one driving factor includes at least one of acceleration, braking, or cornering.

As further shown in FIG. 5, process 500 may include determining a health status of the one or more vehicle components based on comparing the vehicle data with the one or more vehicle component health profiles (block 540). For example, the device may determine a health status of the one or more vehicle components based on comparing the vehicle data with the one or more vehicle component health profiles, as described above.

In some implementations in which one vehicle component, of the one or more vehicle components, includes a battery, a failure state of the battery occurs when a voltage measurement, of the plurality of voltage measurements, is at least a number of standard deviations, of the corresponding number of standard deviations, below a mean, of the corresponding means, of a battery health profile of the one or more vehicle component health profiles. In such implementations, one environmental factor, of the one or more environmental factors and on which the battery health profile is based at least in part, is temperature associated with the plurality of geographical areas forming the geographical region associated with the vehicle.

In some implementations in which one vehicle component, of the one or more vehicle components, includes an air filter, a failure state of the air filter occurs when a pressure differential measurement, of the plurality of pressure differential measurements, is at least a number of standard deviations, of the corresponding number of standard deviations, above a mean, of the corresponding means, of an air filter health profile of the one or more vehicle component health profiles. In such implementations, one environmental factor, of the one or more environmental factors and on which the air filter health profile is based at least in part, is precipitation associated with the plurality of geographical areas forming the geographical region associated with the vehicle.

In some implementations in which one vehicle component, of the one or more vehicle components, includes one or more brake pads, a failure state of the one or more brake pads occurs when a number of harsh braking events is at least a number of standard deviations, of the corresponding number of standard deviations, above a mean, of the corresponding means, of a brake pad health profile of the one or more vehicle component health profiles. In such implementations, one environmental factor, of the one or more environmental factors and on which the brake pad health profile is based at least in part, is precipitation associated with the plurality of geographical areas forming the geographical region associated with the vehicle. In some implementations, a harsh braking event occurs when the deceleration exceeds a braking threshold.

In some implementations in which one vehicle component, of the one or more vehicle components, includes one or more tires, a failure state of the one or more tires occurs when a cumulative number of harsh braking events, harsh acceleration events, and harsh cornering events is at least a number of standard deviations, of the corresponding number of standard deviations, above a mean, of the corresponding means, of a tire health profile of the one or more vehicle component health profiles. In such implementations, one environmental factor, of the one or more environmental factors and on which the tire health profile is based at least in part, is temperature associated with the plurality of geographical areas forming the geographical region associated with the vehicle. In some implementations, a harsh braking event occurs when the deceleration exceeds a braking threshold. In some implementations, a harsh acceleration event occurs when the longitudinal acceleration exceeds an acceleration threshold. In some implementations, a harsh cornering event occurs when the lateral acceleration exceeds a cornering threshold.

In some implementations, process 500 includes determining that one vehicle component, of the one or more vehicle components, is in a failure state, and transmitting, to a client device, repair shop data indicating one or more repair shops within a distance threshold of the vehicle.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

To the extent the aforementioned implementations collect, store, or employ personal information of individuals, it should be understood that such information shall be used in accordance with all applicable laws concerning protection of personal information. Additionally, the collection, storage, and use of such information can be subject to consent of the individual to such activity, for example, through well known “opt-in” or “opt-out” processes as can be appropriate for the situation and type of information. Storage and use of personal information can be in an appropriately secure manner reflective of the type of information, for example, through various encryption and anonymization techniques for particularly sensitive information.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

In the preceding specification, various example embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A method, comprising:
receiving, by a device, vehicle data from one or more vehicle telematics devices,
wherein the vehicle data indicates information relating to one or more vehicle components of a vehicle;
determining, by the device, a geographical region, of a plurality of geographical regions, associated with the vehicle,
wherein the plurality of geographical regions are formed from a plurality of geographical areas that have similarities in one or more environmental factors associated with the plurality of geographical areas;
comparing, by the device, the vehicle data with one or more vehicle component health profiles corresponding to the one or more vehicle components,
wherein the one or more vehicle component health profiles are based at least in part on the geographical region associated with the vehicle,
wherein the one or more vehicle component health profiles indicate failure thresholds for the one or more vehicle components, and
wherein the failure thresholds are based on corresponding numbers of standard deviations from corresponding means of the one or more vehicle component health profiles; and
determining, by the device, a health status of the one or more vehicle components based on comparing the vehicle data with the one or more vehicle component health profiles.

2. The method of claim 1, wherein the one or more environmental factors includes one or more of temperature, precipitation, or humidity associated with the plurality of geographical areas.

3. The method of claim 1, wherein the one or more vehicle component health profiles are further based on road terrain, and
wherein the road terrain is classified in one of a plurality of categories including a highway terrain, a local terrain, and a rural terrain.

4. The method of claim 1, wherein the one or more vehicle component health profiles are further based on a driver profile, and
wherein the driver profile is determined based at least in part on one or more conditions.

5. The method of claim 4, wherein the one or more conditions includes a measurement, which corresponds to at least one driving factor, exceeding a threshold or a minimum duration, and
wherein the at least one driving factor includes at least one of acceleration, braking, or cornering.

6. The method of claim 1, wherein one vehicle component, of the one or more vehicle components, includes a battery,
wherein the information indicated by the vehicle data includes a plurality of voltage measurements of the battery,
wherein a failure state of the battery occurs when a voltage measurement, of the plurality of voltage measurements, is at least a number of standard deviations, of the corresponding number of standard deviations, below a mean, of the corresponding means, of a battery health profile of the one or more vehicle component health profiles, and
wherein one environmental factor, of the one or more environmental factors and on which the battery health profile is based at least in part, is temperature associated with the plurality of geographical areas forming the geographical region associated with the vehicle.

7. The method of claim 1, wherein one vehicle component, of the one or more vehicle components, includes an air filter,
wherein the information indicated by the vehicle data includes a plurality of pressure differential measurements across the air filter,
wherein a failure state of the air filter occurs when a pressure differential measurement, of the plurality of pressure differential measurements, is at least a number of standard deviations, of the corresponding number of standard deviations, above a mean, of the corresponding means, of an air filter health profile of the one or more vehicle component health profiles, and
wherein one environmental factor, of the one or more environmental factors and on which the air filter health profile is based at least in part, is precipitation associated with the plurality of geographical areas forming the geographical region associated with the vehicle.

8. The method of claim 1, wherein one vehicle component, of the one or more vehicle components, includes one or more brake pads,
wherein the information indicated by the vehicle data includes deceleration,
wherein a harsh braking event occurs when the deceleration exceeds a braking threshold,
wherein a failure state of the one or more brake pads occurs when a number of harsh braking events is at least a number of standard deviations, of the corresponding number of standard deviations, above a mean, of the corresponding means, of a brake pad health profile of the one or more vehicle component health profiles, and
wherein one environmental factor, of the one or more environmental factors and on which the brake pad health profile is based at least in part, is precipitation associated with the plurality of geographical areas forming the geographical region associated with the vehicle.

9. The method of claim 1, wherein one vehicle component, of the one or more vehicle components, includes one or more tires,
wherein the information indicated by the vehicle data includes lateral acceleration, longitudinal acceleration, and deceleration,
wherein a harsh braking event occurs when the deceleration exceeds a braking threshold,
wherein a harsh acceleration event occurs when the longitudinal acceleration exceeds an acceleration threshold,
wherein a harsh cornering event occurs when the lateral acceleration exceeds a cornering threshold,
wherein a failure state of the one or more tires occurs when a cumulative number of harsh braking events, harsh acceleration events, and harsh cornering events is at least a number of standard deviations, of the corresponding number of standard deviations, above a mean, of the corresponding means, of a tire health profile of the one or more vehicle component health profiles, and
wherein one environmental factor, of the one or more environmental factors and on which the tire health profile is based at least in part, is temperature associated with the plurality of geographical areas forming the geographical region associated with the vehicle.

10. The method of claim 1, further comprising:
determining that one vehicle component, of the one or more vehicle components, is in a failure state; and
transmitting, to a client device, repair shop data indicating one or more repair shops within a distance threshold of the vehicle.

11. A device, comprising:
one or more processors configured to:
determine a plurality of geographical regions based at least in part on similarities in one or more environmental factors;
receive vehicle data from a plurality of vehicle telematic devices associated with a plurality of vehicles,
wherein the vehicle data indicates vehicle information relating to one or more vehicle components of the plurality of vehicles, and vehicle geographical locations associated with the plurality of vehicles;
generate, based on the vehicle information and the vehicle geographical locations, one or more vehicle component health profiles for combinations of a vehicle component, of the one or more vehicle components, and a geographical region, of the plurality of geographical regions, in which a particular vehicle, of the plurality of vehicles, was located when receiving the vehicle data corresponding to the particular vehicle;
wherein the one or more vehicle component health profiles indicate failure thresholds for the one or more vehicle components;
receive account vehicle data from an account vehicle from one or more account vehicle telematics devices,
wherein the account vehicle data indicates information relating to one or more account vehicle components of the account vehicle;
determine a geographical region, of the plurality of geographical regions, associated with the account vehicle; and
determine a health status of the one or more vehicle components based on a comparison of the account vehicle data with the one or more vehicle component health profiles.

12. The device of claim 11, wherein the one or more vehicle components include at least one of a battery, one or more tires, one or more brake pads, or an air filter.

13. The device of claim 12, wherein the information indicated by the vehicle data includes a plurality of voltage measurements of the battery,
wherein a failure state of the battery occurs when a voltage measurement, of the plurality of voltage measurements, is at least a number of standard deviations below a mean of a battery health profile of the one or more vehicle component health profiles, and
wherein one environmental factor, of the one or more environmental factors and on which the battery health profile is based at least in part, is temperature associated with a plurality of geographical areas forming the geographical region associated with the account vehicle.

14. The device of claim 12, wherein the information indicated by the vehicle data includes a plurality of pressure differential measurements across the air filter,
wherein a failure state of the air filter occurs when a pressure differential measurement, of the plurality of pressure differential measurements, is at least a number of standard deviations above a mean of an air filter health profile of the one or more vehicle component health profiles, and
wherein one environmental factor, of the one or more environmental factors and on which the air filter health profile is based at least in part, is precipitation associated with a plurality of geographical areas forming the geographical region associated with the account vehicle.

15. The device of claim 12, wherein the information indicated by the vehicle data includes deceleration,
wherein a harsh braking event occurs when the deceleration exceeds a braking threshold,
wherein a failure state of the one or more brake pads occurs when a number of harsh braking events is at least a number of standard deviations above a mean of a brake pad health profile of the one or more vehicle component health profiles, and
wherein one environmental factor, of the one or more environmental factors and on which the brake pad health profile is based at least in part, is precipitation associated with a plurality of geographical areas forming the geographical region associated with the account vehicle.

16. The device of claim 12, wherein the information indicated by the vehicle data includes lateral acceleration, longitudinal acceleration, and deceleration,
wherein a harsh braking event occurs when the deceleration exceeds a braking threshold,
wherein a harsh acceleration event occurs when the longitudinal acceleration exceeds an acceleration threshold,
wherein a harsh cornering event occurs when the lateral acceleration exceeds a cornering threshold,
wherein a failure state of the one or more tires occurs when a cumulative number of harsh braking events, harsh acceleration events, and harsh cornering events is at least a number of standard deviations above a mean of a tire health profile of the one or more vehicle component health profiles, and
wherein one environmental factor, of the one or more environmental factors and on which the tire health profile is based at least in part, is temperature associated with a plurality of geographical areas forming the geographical region associated with the account vehicle.

17. A non-transitory computer-readable medium storing a set of instructions, the set of instructions comprising:
one or more instructions that, when executed by one or more processors of a device, cause the device to:
receive vehicle data from one or more vehicle telematics devices,
wherein the vehicle data indicates information relating to one or more vehicle components of a vehicle;
determine a geographical region, of a plurality of geographical regions, associated with the vehicle,
wherein the plurality of geographical regions are determined based at least in part on similarities in one or more environmental factors;
determine a health status of the one or more vehicle components based on a comparison of the vehicle data with one or more vehicle component health profiles corresponding to the one or more vehicle components,
wherein the one or more vehicle component health profiles are based at least in part on the geographical region associated with the vehicle, and
wherein the one or more vehicle component health profiles indicate failure thresholds for the one or more vehicle components; and
transmit, to a client device, vehicle component health data indicating a health status of the one or more vehicle components.

18. The non-transitory computer-readable medium of claim 17, wherein the one or more instructions, when executed by the one or more processors, further cause the device to:
receive collected vehicle data from a plurality of profile vehicle telematic devices associated with a plurality of profile vehicles,
wherein the collected vehicle data indicates profile vehicle information relating to one or more profile vehicle components of the plurality of profile vehicles, and profile vehicle geographical locations associated with the plurality of profile vehicles;
determine, based on the profile vehicle geographical locations, in which geographical regions, of the plurality of geographical regions, the plurality of profile vehicles are located when receiving the collected vehicle data; and
generate, based on the profile vehicle information and the profile vehicle geographical locations, the one or more vehicle component health profiles,
wherein the one or more vehicle component health profiles correspond to one or more combinations of one of the one or more profile vehicle components and one of the plurality of geographical regions.

19. The non-transitory computer readable medium of claim 17, wherein the one or more vehicle component health profiles are further based on road terrain, and
wherein the road terrain is classified in one of a plurality of categories including a highway terrain, a local terrain, and a rural terrain.

20. The non-transitory computer readable medium of claim 17, wherein the one or more vehicle component health profiles are further based on a driver profile,
wherein the driver profile is determined based at least in part on one or more measurements, which correspond to one or more driving factors, exceeding a threshold or a minimum duration, and
wherein the one or more driving factors includes at least one of acceleration, braking, or cornering.
